(19) United States
(12) Patent Application Publication
(10) Pub. No.: US 2025/0136865 A1
(43) Pub. Date: May 1, 2025

(54) Etching Compositions

(71) Applicant: Fujifilm Electronic Materials U.S.A., Inc., N. Kingstown, RI (US)

(72) Inventors: Keeyoung Park, Chandler, AZ (US); Kohei Hayashi, Gilbert, AZ (US); Kazutaka Takahashi, Gilbert, AZ (US); Mick Bjelopavlic, Chandler, AZ (US)

(21) Appl. No.: 18/931,148

(22) Filed: Oct. 30, 2024

Related U.S. Application Data
(60) Provisional application No. 63/546,795, filed on Nov. 1, 2023.

(51) Int. Cl. C09K 13/08; H01L 21/02; H01L 21/306

(52) U.S. Cl. CPC C09K 13/08; H01L 21/02057; H01L 21/30604

(57) ABSTRACT

The present disclosure is directed to etching compositions that are useful for, e.g., selectively removing silicon germanium (SiGe) from a semiconductor substrate as an intermediate step in a multistep semiconductor manufacturing process.

### CROSS-REFERENCE TO RELATED APPLICATION

The present application claims priority to U.S. Provisional Application Ser. No. 63/546,795, filed on Nov. 1, 2023, the contents of which are hereby incorporated by reference in their entirety.

### FIELD OF THE DISCLOSURE

The present disclosure relates to etching compositions and processes of using etching compositions. In particular, the present disclosure relates to etching compositions that can selectively etch silicon germanium in the presence of other exposed or underlying materials, such as metal conductors (e.g., copper), barrier materials, insulator materials (e.g., low-k dielectric materials).

### BACKGROUND OF THE DISCLOSURE

The semiconductor industry is rapidly decreasing the dimensions and increasing the density of electronic circuitry and electronic components in microelectronic devices, silicon chips, liquid crystal displays, MEMS (Micro Electro Mechanical Systems), printed wiring boards, and the like. The integrated circuits within them are being layered or stacked with constantly decreasing thicknesses of the insulating layer between each circuitry layer and smaller and smaller feature sizes. As the feature sizes have shrunk, patterns have become smaller, and device performance parameters tighter and more robust. As a result, various issues which heretofore could be tolerated, can no longer be tolerated or have become more of an issue due to the smaller feature size.

In the production of advanced integrated circuits, to minimize problems associated with the higher density and to optimize performance, both high k and low k insulators, and assorted barrier layer materials have been employed.

Silicon germanium (SiGe) can be utilized in the manufacturing of semiconductor devices, liquid crystal displays, MEMS (Micro Electro Mechanical Systems), printed wiring boards and the like, as nanowires and/or nanosheets. For example, it can be used as a gate material in a multigate device, such as a multiple-gate field-effect transistor (FET) (e.g., a gate-all-around FET).

### SUMMARY OF THE DISCLOSURE

In the construction of semiconductor devices, silicon germanium (SiGe) frequently needs to be etched. In the various types of uses and device environments of SiGe, other layers are in contact with or otherwise exposed at the same time as this material is etched. Highly selective etching of the SiGe in the presence of these other materials (e.g., metal conductors, dielectric, and hard marks) is typically needed for device yield and long life. The etching process for the SiGe may be a plasma etching process. However, using a plasma etching process on the SiGe layer may cause damage to either or both the gate insulating layer and the semiconductor substrate. In addition, the etching process may remove a portion of the semiconductor substrate by etching the gate insulating layer exposed by the gate electrode. The electrical characteristics of the transistor may be negatively impacted. To avoid such etching damage, additional protective device manufacturing steps may be employed, but at a significant cost.

The present disclosure relates to compositions and processes for selectively etching SiGe relative to hard mask layers, gate materials (e.g., SiN, poly-Si, or SiOx) and low-k dielectric layers (e.g., SiN, poly-Si, SiOx, carbon doped oxide, or SiCO) that are present in the semiconductor device. More specifically, the present disclosure relates to compositions and processes for selectively etching SiGe relative to low-k dielectric layers.

In some embodiments, the disclosure provides etching compositions, including:
at least one fluorine-containing acid, the at least one fluorine-containing acid including hydrofluoric acid or hexafluorosilicic acid;
at least one oxidizing agent;
at least one organic acid or an anhydride thereof, or a combination thereof;
at least one silicon-containing compound;
and
water.

In some embodiments, the at least one fluorine-containing acid is in an amount of from about 0.01 wt % to about 2 wt % of the composition.

In some embodiments, the at least one oxidizing agent includes hydrogen peroxide or peracetic acid. In some embodiments, the at least one oxidizing agent is in an amount of from about 5 wt % to about 10 wt % of the composition.

In some embodiments, the at least one organic acid includes formic acid, acetic acid, propionic acid, or butyric acid. In some embodiments, the at least one anhydride thereof includes formic anhydride, acetic anhydride, propionic anhydride, or butyric anhydride. In some embodiments, the composition includes an organic acid and an anhydride thereof. In some embodiments, the organic acid is acetic acid and the anhydride is acetic anhydride. In some embodiments, the at least one organic acid is in an amount of from about 10 wt % to about 30 wt % of the composition, and the at least one anhydride thereof is in an amount of from about 40 wt % to about 70 wt % of the composition.

In some embodiments, the silicon-containing compound includes a siloxane or a silazane. In some embodiments, the silicon-containing compound is tetraethoxysilane, triethoxymethylsilane, hexamethyldisilazane, or tetramethyldisilazane. In some embodiments, the silicon-containing compound is a silane-modified polymer. In some embodiments, the silane-modified polymer includes a silane-modified olefin polymer. In some embodiments, the silane-modified olefin polymer is polyethylene, polypropylene, polybutadiene, polyisoprene, polystyrene, or copolymers thereof. In some embodiments, the silane-modified polymer includes polybutadiene. In some embodiments, the silane-modified polymer includes at least one trialkoxysilyl moiety. In some embodiments, each alkoxy moiety is independently C₁-C₅ alkoxy.

In some embodiments, the water is in an amount of from about 5 wt % to about 30 wt % of the composition.

In some embodiments, the etching compositions of the disclosure further include at least one polymerized naphthalene sulfonic acid. In some embodiments, the at least one polymerized naphthalene sulfonic acid includes a sulfonic acid having a structure of

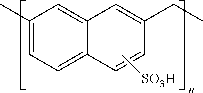

in which n is 3 to 6.

In some embodiments, the at least one polymerized naphthalene sulfonic acid is in an amount of from about 0.005 wt % to about 0.15 wt % of the composition.

In some embodiments, the etching compositions of the disclosure further include at least one amine, the at least one amine including an amine of formula (I): N—R₁R₂R₃, wherein R¹ is C₁-C₈ alkyl optionally substituted by OH or NH₂, R₂ is H or C₁-C₈ alkyl optionally substituted by OH, and R₃ is C₁-C₈ alkyl optionally substituted by OH. In some embodiments, the amine of formula (I) is diisopropylamine, N-butyldiethanolamine, N-(3-aminopropyl)-diethanolamine, N-octylglucamine, N-ethylglucamine, N-methylglucamine, or 1-[bis(2-hydroxyethyl)amino]-2-propanol. In some embodiments, the at least one amine is in an amount of from about 0.001 wt % to about 0.15 wt % of the composition.

In some embodiments, the etching compositions of the disclosure further include an inorganic acid. In some embodiments, the inorganic acid is sulfuric acid, nitric acid, or phosphoric acid.

In some embodiments, the etching compositions of the disclosure have a pH less than 1.

In some embodiments the disclosure provides methods, including:
contacting a semiconductor substrate containing a SiGe film with a composition of the disclosure to substantially remove the SiGe film. In some embodiments, the SiGe film includes from about 10 wt % to about 30 wt % Ge.

In some embodiments, the methods of the disclosure further include rinsing the semiconductor substrate with a rinse solvent after the contacting step. In some embodiments, the methods of the disclosure further include drying the semiconductor substrate after the rinsing step.

In some embodiments, the methods of the disclosure do not substantially remove SiN, poly-Si, or SiCO.

In some embodiments, the disclosure provides articles formed by the methods of the disclosure, wherein the articles are semiconductor devices. In some embodiments, the semiconductor device is an integrated circuit.

### DETAILED DESCRIPTION OF THE DISCLOSURE

As defined herein, unless otherwise noted, all percentages expressed should be understood to be percentages by weight to the total weight of the composition. Unless otherwise noted, ambient temperature is defined to be between about 16 and about 27 degrees Celsius (° C.).

In general, the disclosure features etching compositions (e.g., etching compositions for selectively removing SiGe) that include at least one fluorine-containing acid, the at least one fluorine-containing acid including hydrofluoric acid or hexafluorosilicic acid;
at least one oxidizing agent;
at least one organic acid or an anhydride thereof, or a combination thereof;
at least one silicon-containing compound;
and
water.

In general, the etching compositions of this disclosure can include at least one (e.g., two, three, or four) fluorine-containing agent. The fluorine-containing acid described herein can be an inorganic acid, such as HF or H₂SiF₆. In some embodiments, the at least one fluorine-containing acid is in an amount of at least about 0.01 wt % (e.g., at least about 0.02% by weight, at least about 0.03% by weight, at least about 0.04% by weight, at least about 0.05% by weight, at least about 0.1% by weight, at least about 0.2 wt %, at least about 0.4 wt %, at least about 0.5 wt %, at least about 0.6 wt %, at least about 0.8 wt %, at least about 1 wt %, at least about 1.2 wt %, at least about 1.4 wt %, or at least about 1.5 wt %) to at most about 2 wt % (e.g., at most about 1.9 wt %, at most about 1.8 wt %, at most about 1.7 wt %, at most about 1.6 wt %, at most about 1.5 wt %, at most about 1.2 wt %, at most about 1 wt %, or at most about 0.5 wt %) of the etching composition of this disclosure. Without wishing to be bound by theory, it is believed that fluorine-containing acid can facilitate and enhance the removal of SiGe on a semiconductor substrate during the etching process.

The etching composition of this disclosure can include at least one (e.g., two, three, or four) oxidizing agent suitable for use in microelectronic applications. Examples of suitable oxidizing agents include, but are not limited to, oxidizing acids or salts thereof (e.g., nitric acid, permanganic acid, or potassium permanganate), peroxides (e.g., hydrogen peroxide, dialkylperoxides, urea hydrogen peroxide), persulfonic acid (e.g., hexafluoropropanepersulfonic acid, methanepersulfonic acid, trifluoromethanepersulfonic acid, or p-toluenepersulfonic acid) and salts thereof, ozone, peroxycarboxylic acids (e.g., peracetic acid) and salts thereof, perphosphoric acid and salts thereof, persulfuric acid and salts thereof (e.g., ammonium persulfate or tetramethylammonium persulfate), perchloric acid and salts thereof (e.g., ammonium perchlorate, sodium perchlorate, or tetramethylammonium perchlorate)), and periodic acid and salts thereof (e.g., periodic acid, ammonium periodate, or tetramethylammonium periodate). These oxidizing agents can be used singly or in combination.

In some embodiments, the at least one oxidizing agent can be from at least about 5% by weight (e.g., at least about 6% by weight, at least about 7% by weight, at least about 8% by weight, at least about 9% by weight, at least about 10% by weight, at least about 11% by weight, at least about 13% by weight, or at least about 15% by weight) to at most about 20% by weight (e.g., at most about 18 wt %, at most about 16 wt %, at most about 15 wt %, at most about 14 wt %, at most about 12 wt %, or at most about 10 wt %) of the etching composition of this disclosure. Without wishing to be bound by theory, it is believed that the oxidizing agent can facilitate and enhance the removal of SiGe on a semiconductor substrate.

In general, the etching composition of this disclosure can include at least one (e.g., two, three, or four) organic acid or an anhydride thereof. In some embodiments, the organic acid can be formic acid, acetic acid, propionic acid, or butyric acid. In some embodiments, the organic acid anhydride can be formic anhydride, acetic anhydride, propionic anhydride, or butyric anhydride. In some embodiments, the at least one organic acid can be from at least about 10 wt % (e.g., at least about 15% by weight, at least about 20% by weight, at least about 25% by weight, at least about 30% by weight, or at least about 35% by weight) to at most about 40 wt % (e.g., at most about 35 wt %, at most about 30 wt %, at most about 25 wt %, at most about 20 wt %, or at most about 15 wt %) of the etching composition of this disclosure. In some embodiments, the at least one anhydride thereof can be from at least about 30% by weight (e.g., at least about 35% by weight, at least about 40% by weight, at least about 45% by weight, at least about 50% by weight, at least about 55% by weight, or at least about 60% by weight) to at most about 90% by weight (e.g., at most about 85 wt %, at most about 80 wt %, at most about 75 wt %, at most about 70 wt %, at most about 65 wt %, at most about 60 wt %, at most about 55 wt %, at most about 50 wt %, at most about 45 wt %, or at most about 40 wt %) of the etching composition of this disclosure. Without wishing to be bound by theory, it is believed that the organic acid or an anhydride thereof can facilitate and enhance the removal of SiGe on a semiconductor substrate.

The etching composition of this disclosure can generally include at least one polymerized naphthalene sulfonic acid (or poly (naphthalene sulfonic acid)), e.g., as a surfactant or selective inhibitor. In some embodiments, the polymerized naphthalene sulfonic acid can be a sulfonic acid having the following chemical structure:

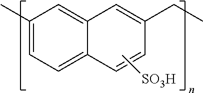

in which n is 3, 4, 5, or 6. Commercially available examples of such the polymerized naphthalene sulfonic acids include Takesurf A-47 series products available from Takemoto Oil & Fat Co., Ltd. In some embodiments, the at least one polymerized naphthalene sulfonic acid can be from at least about 0.005% by weight (e.g., at least about 0.01% by weight, at least about 0.02% by weight, at least about 0.03% by weight, at least about 0.04% by weight, at least about 0.05% by weight, or at least about 0.1% by weight) to at most about 0.15% by weight (e.g., at most about 0.14 wt %, at most about 0.12 wt %, at most about 0.1 wt %, at most about 0.08 wt %, at most about 0.06 wt %, or at most about 0.05 wt %) of the etching composition of this disclosure. Without wishing to be bound by theory, it is believed that the polymerized naphthalene sulfonic acid can selectively inhibit the removal of SiN, poly-Si, and SiCO when SiGe is removed from a semiconductor substrate using the etching composition of this disclosure.

In general, the etching compositions of this disclosure can include at least one (e.g., two, three, or four) amine. In some embodiments, the amine can be an amine of formula (I): N—R₁R₂R₃, wherein R¹ is C₁-C₈ alkyl optionally substituted by OH or NH₂, R₂ is H or C₁-C₈ alkyl optionally substituted by OH, and R₃ is C₁-C₈ alkyl optionally substituted by OH. Examples of suitable amines of formula (I) include diisopropylamine, N-butyldiethanolamine, N-(3-aminopropyl)-diethanolamine, N-octylglucamine, N-ethylglucamine, N-methylglucamine, and 1-[bis(2-hydroxyethyl)amino]-2-propanol.

In some embodiments, the at least one amine can be from at least about 0.001% by weight (e.g., at least about 0.002% by weight, at least about 0.005% by weight, at least about 0.008% by weight, at least about 0.01% by weight, at least about 0.02% by weight, at least about 0.05% by weight, or at least about 0.1% by weight) to at most about 0.15% by weight (e.g., at most about 0.14 wt %, at most about 0.12 wt %, at most about 0.1 wt %, at most about 0.08 wt %, at most about 0.06 wt %, or at most about 0.05 wt %) of the etching composition of this disclosure. Without wishing to be bound by theory, it is believed that the amine can selectively inhibit the removal of SiN, poly-Si, and SiCO when SiGe is removed from a semiconductor substrate using the etching composition of this disclosure.

In some embodiments, the etching compositions of the disclosure include at least one silicon-containing compound. In some embodiments, the silicon-containing compound includes a siloxane or a silazane. In some embodiments, the silicon-containing compound is tetraethoxysilane, triethoxymethylsilane, hexamethyldisilazane, or tetramethyldisilazane.

Further examples of silicon-containing compounds contemplated for use in the compositions of the disclosure include, but are not limited to, hexamethyldisiloxane, 1,3-diphenyl-1,3-dimethyldisiloxane, 1,1,3,3-tetramethyldisiloxane, 1,1,1-triethyl-3,3-dimethyldisiloxane, 1,1,3,3-tetra-n-octyldimethyldisiloxane, bis (nonafluorohexyl) tetramethyldisiloxane, 1,3-bis(trifluoropropyl) tetramethyldisiloxane, 1,3-di-n-butyltetramethyldisiloxane, 1,3-di-n-octyltetramethyldisiloxane, 1,3-diethyltetramethyldisiloxane, 1,3-diphenyltetramethyldisiloxane, hexa-n-butyldisiloxane, hexaethyldisiloxane, hexavinyldisiloxane, 1,1,1,3,3-pentamethyl-3-acetoxydisiloxane, 1-allyl-1,1,3,3-tetramethyldisiloxane, 1,3-bis(3-aminopropyl) tetramethyldisiloxane, 1,3-bis(heptadecafluoro-1,1,2,2-tetrahydrodecyl) tetramethyldisiloxane, 1,3-divinyltetraphenyldisiloxane, 1,3-divinyltetramethyldisiloxane, 1,3-diallyltetrakis (trimethylsiloxy) disiloxane, 1,3-diallyltetramethyldisiloxane, 1,3-diphenyltetrakis (dimethylsiloxy) disiloxane, (3-chloropropyl) pentamethyldisiloxane, 1,3-divinyltetrakis (trimethylsiloxy) disiloxane, 1,1,3,3-tetraisopropyldisiloxane, 1,1,3,3-tetravinyldimethyldisiloxane, 1,1,3,3-tetracyclopentyldichlorodisiloxane, vinylpentamethyldisiloxane, 1,3-bis(3-chloroisobutyl) tetramethyldisiloxane, hexaphenyldisiloxane, 1,3-bis [(bicyclo[2.2.1]hept-2-enyl) ethyl] tetramethyldisiloxane, 1,1,1-triethyl-3,3,3-trimethyldisiloxane, 1,3-bis(3-methacryloxypropyl) tetramethyldisiloxane, 1,3-bis(chloromethyl) tetramethyldisiloxane, 1,1,3,3-tetramethyl-1,3-diethoxydisiloxane, 1,1,3,3-tetraphenyldimethyldisiloxane, methacryloxypentamethyldisiloxane, pentamethyldisiloxane, 1,3-bis(3-chloropropyl) tetramethyldisiloxane, 1,3-bis(4-hydroxybutyl) tetramethyldisiloxane, 1,3-bis(triethoxysilylethyl) tetramethyldisiloxane, 3-aminopropylpentamethyldisiloxane, 1,3-bis(2-aminoethylaminomethyl) tetramethyldisiloxane, 1,3-bis(3-carboxypropyl) tetramethyldisiloxane, 1,3-dichloro-1,3-diphenyl-1,3-dimethyldisiloxane, 1,3-diethynyltetramethyldisiloxane, n-butyl-1,1,3,3-tetramethyldisiloxane, 1,3-dichlorotetraphenyldisiloxane, 1,3-dichlorotetramethyldisiloxane, 1,3-di-t-butyldisiloxane, 1,3-dimethyltetramethoxydisiloxane, 1,3-divinyltetraethoxydisiloxane, 1, 1,3,3-tetraethoxy-1,3-dimethyldisiloxane, vinyl-1, 1,3,3-tetramethyldisiloxane, platinum-[1,3-bis (cyclohexyl) imidazol-2-ylidene] [hexachlorodisiloxane], 1,1,3,3-tetraisopropyl-1-chlorodisiloxane, 1,1,1-trimethyl-3,3,3-triphenyldisiloxane, 1,3-bis(trimethylsiloxy)-1,3-dimethyldisiloxane, 3,3-diphenyltetramethyltrisiloxane, 3-phenylheptamethyltrisiloxane, hexamethylcyclotrisiloxane, n-propylheptamethyltrisiloxane, 1,5-diethoxyhexamethyltrisiloxane, 3-ethylheptamethyltrisiloxane, 3-(tetrahydrofurfuryloxypropyl) heptamethyltrisiloxane, 3-(3,3,3-trifluoropropyl) heptamethyltrisiloxane, 1,1,3,5,5-pentaphenyl-1,3,5-trimethyltrisiloxane, octamethyltrisiloxane, 1,1,5,5-tetraphenyl-1,3,3,5-tetramethyltrisiloxane, hexaphenylcyclotrisiloxane, 1,1, 1,5,5,5-hexamethyltrisiloxane, octachlorotrisiloxane, 3-phenyl-1,1,3,5,5-pentamethyltrisiloxane, (3,3,3-trifluoropropyl)methylcyclotrisiloxane, 1,3,5-trivinyl-1,1,3,5,5-pentamethyltrisiloxane, 1,3,5-trivinyl-1,3,5-trimethylcyclotrisiloxane, 3-(3-acetoxypropyl) heptamethyltrisiloxane, 3-(m-pentadecylphenoxypropyl) heptamethyltrisiloxane, limonenyltrisiloxane, 3-dodecylheptamethyltrisiloxane, 3-octylheptamethyltrisiloxane, 1,3,5-triphenyltrimethylcyclotrisiloxane, 1,1,1,3,3,5,5-heptamethyltrisiloxane, 1,1,3,3,5,5-hexamethyltrisiloxane, 1,1,1,5,5,5-hexaethyl-3-methyltrisiloxane, 1,5-dichlorohexamethyltrisiloxane, 3-triacontylheptamethyltrisiloxane, 3-(3-hydroxypropyl) heptamethyltrisiloxane, hexamethylcyclomethylphosphonoxytrisiloxane, 3-octadecylheptamethyltrisiloxane, furfuryloxytrisiloxane, tetrakis (dimethylsiloxy) silane, 1,1,3,3,5,5,7,7-octamethyltetrasiloxane, a diphenylsiloxane-dimethylsiloxane copolymer, 1,3-diphenyl-1,3-dimethyldisiloxane, octamethylcyclotetrasiloxane, 1,3-bis(trimethylsiloxy)-1,3-dimethyldisiloxane, a dimethylsiloxane-[65-70 percent (60 percent propylene oxide/40 percent ethylene oxide)] block copolymer, bis(hydroxypropyl) tetramethyldisiloxane, tetra-n-propyltetramethylcyclotetrasiloxane, octaethylcyclotetrasiloxane, decamethyltetrasiloxane, dodecamethylcyclohexasiloxane, dodecamethylpentasiloxane, tetradecamethylhexasiloxane, hexaphenylcyclotrisiloxane, polydimethylsiloxane, polyoctadecylmethylsiloxane, hexacosyl terminated polydimethylsiloxane, decamethylcyclopentasiloxane, poly (3,3,3-trifluoropropylmethylsiloxane), trimethylsiloxy terminated polydimethylsiloxane, 1,1,3,3,5,5,7,7,9,9-decamethylpentasiloxane, or triethylsiloxy terminated polydiethylsiloxane.

In some embodiments, the silicon-containing compound is a silane-modified polymer. In some embodiments, the silane-modified polymer is a silane-modified olefin polymer. Silane-modified olefin polymers contemplated include, but are not limited to, polyethylene, polypropylene, polybutadiene, polyisoprene, polystyrene, or copolymers thereof. In some embodiments, the silane-modified polymer includes polybutadiene.

In some embodiments, the silane-modified polymer includes at least one trialkoxysilyl moiety. In some embodiments, each alkoxy moiety is independently a C₁-C₅ alkoxy.

In some embodiments, the silicon-containing compound is present in the compositions of the disclosure in an amount from about 0.005 wt % to about 0.250 wt %.

In general, the etching composition of this disclosure can include water as a solvent. In some embodiments, the water can be de-ionized and ultra-pure, contain no organic contaminants and have a minimum resistivity of about 4 to about 17 mega Ohms, or at least about 17 mega Ohms. In some embodiments, the water is in an amount of from at least about 5 wt % (e.g., at least about 7% by weight, at least about 10% by weight, at least about 13% by weight, or at least about 15%) to at most about 30 wt % (e.g., at most about 29 wt %, at most about 27 wt %, or at most about 25 wt %) of the etching composition. Without wishing to be bound by theory, it is believed that, if the amount of water is greater than 30 wt % of the composition, it would adversely impact the SiGe etch rate, and reduce its removal during the etching process. On the other hand, without wishing to be bound by theory, it is believed that the etching composition of this disclosure should include a certain level of water (e.g., at least about 5 wt %) to keep all other components solubilized and to avoid reduction in the etching performance.

In some embodiments, the etching compositions of the disclosure further include an inorganic acid. In some embodiments, the inorganic acid is sulfuric acid, nitric acid, or phosphoric acid.

In some embodiments, the etching composition of this disclosure can further include at least one (e.g., two, three, or four) organic solvent. In some embodiments, the at least one organic solvent can include an alcohol or an alkylene glycol ether. Examples of suitable organic solvents include propylene glycol, hexylene glycol, 1,3-propanediol, ethylene glycol butyl ether, and 3-methoxy-3-methyl-1-butanol. In some embodiments, the at least one organic solvent can be from at least about 10 wt % (e.g., at least about 15% by weight, at least about 20% by weight, at least about 25% by weight, at least about 30% by weight, or at least about 35% by weight) to at most about 40 wt % (e.g., at most about 35 wt %, at most about 30 wt %, at most about 25 wt %, at most about 20 wt %, or at most about 15 wt %) of the etching composition.

In addition, in some embodiments, the etching composition of the present disclosure may contain additives such as, pH adjusting agents, corrosion inhibitors, surfactants, additional organic solvents, biocides, and defoaming agents as optional components. Examples of suitable additives include alcohols (e.g., polyvinyl alcohol), organic acids (e.g., iminidiacetic acid, malonic acid, oxalic acid, succinic acid, and malic acid), and inorganic acids (e.g., boric acid). Examples of suitable defoaming agents include polysiloxane defoamers (e.g., polydimethylsiloxane), polyethylene glycol methyl ether polymers, ethylene oxide/propylene oxide copolymers, and glycidyl ether capped acetylenic diol ethoxylates (such as those described in U.S. Pat. No. 6,717,019, herein incorporated by reference). Examples of suitable surfactants may be cationic, anionic, nonionic or amphoteric.

In general, the etching composition of the present disclosure can have a relatively high SiGe/dielectric material (e.g., SiN, polysilicon, or SiCO) etch selectivity (i.e., a high ratio of SiGe etch rate over dielectric material etch rate). In some embodiments, the etching composition can have a SiGe/dielectric material etch selectivity of at least about 10 (e.g., at least about 15, at least about 20, at least about 25, at least about 30, at least about 35, at least about 40, at least about 45, at least about 50, at least about 55, at least about 60, at least about 65, at least about 70, or at least about 75) and/or at most about 500 (e.g., at most about 300, at most about 250, at most about 200, or at most about 100).

In some embodiments, the etching compositions of the present disclosure may specifically exclude one or more of the additive components, in any combination, if more than one. Such components are selected from the group consisting of polymers, oxygen scavengers, quaternary ammonium salts (including quaternary ammonium hydroxides such as TMAH), amines, alkaline bases (such as NaOH, KOH, and LiOH), surfactants other than a defoamer, a defoamer, fluoride containing compounds, abrasives, silicates, hydroxycarboxylic acids containing more than two hydroxyl groups, carboxylic and polycarboxylic acids lacking amino groups, silanes (e.g., alkoxysilanes), cyclic compounds (e.g., azoles (such as diazoles, triazoles, or tetrazoles), triazines, and cyclic compounds containing at least two rings, such as substituted or unsubstituted naphthalenes, or substituted or unsubstituted biphenylethers), buffering agents, non-azole corrosion inhibitors, and metal salts (e.g., metal halides).

The etching composition of this disclosure can be prepared by simply mixing the components together, or may be prepared by blending two compositions in a kit. The first composition in the kit can be an aqueous solution of an oxidizing agent (e.g., H₂O₂). The second composition in the kit can contain the remaining components of the etching composition of this disclosure at predetermined ratios in a concentrated form such that the blending of the two compositions will yield a desired etching composition of the disclosure.

In some embodiments, the present disclosure features a method of etching a semiconductor substrate containing at least one SiGe film. The method can include contacting a semiconductor substrate containing the at least one SiGe film with an etching composition of this disclosure to remove the SiGe film. In some embodiments, the method substantially removes the SiGe film. The method can further include rinsing the semiconductor substrate with a rinse solvent after the contacting step and/or drying the semiconductor substrate after the rinsing step. In some embodiments, the method does not substantially remove a metal conductor (e.g., Cu) or a dielectric material (e.g., SiN, polysilicon, or SiCO) in the semiconductor substrate. For example, the method does not remove more than about 5% by weight (e.g., more than about 3% by weight or more than about 1% by weight) of a metal conductor or a dielectric material in the semiconductor substrate.

In some embodiments, the SiGe film in a semiconductor substrate can include at least about 10 wt % (e.g., at least about 12 wt %, at least about 14 wt %, at least about 15 wt %, at least about 16 wt %, at least about 18 wt %, or at least about 20 wt %) and/or at most about 35 wt % (e.g., at most about 34 wt %, at most about 32 wt %, at most about 30 wt %, at most about 28 wt %, at most about 26 wt %, at most about 25 wt %, at most about 24 wt %, at most about 22 wt %, at most about 20 wt %, at most about 18 wt %, at most about 16 wt %, or at most about 15 wt %) Ge in the SiGe film. Without wishing to be bound by theory, it is believed that a SiGe film containing from about 10 wt % to about 35 wt % Ge can be more easily removed from a semiconductor substrate by an etching composition compared to a film containing more than 35 wt % or less than 10 wt % Ge.

In some embodiments, the etching method includes the steps of:
(A) providing a semiconductor substrate containing a SiGe film;
(B) contacting the semiconductor substrate with an etching composition described herein;
(C) rinsing the semiconductor substrate with one or more suitable rinse solvents; and
(D) optionally, drying the semiconductor substrate (e.g., by any suitable means that removes the rinse solvent and does not compromise the integrity of the semiconductor substrate).

The semiconductor substrates containing SiGe to be etched in this method can contain organic and organometallic residues, and a range of metal oxides, some or all of which may also be removed during the etching process.

Semiconductor substrates described herein (e.g., wafers) typically are constructed of silicon, silicon germanium, Group III-V compounds such as GaAs, or any combination thereof. The semiconductor substrates can additionally contain exposed integrated circuit structures such as interconnect features (e.g., metal lines and dielectric materials). Metals and metal alloys used for interconnect features include, but are not limited to, aluminum, aluminum alloyed with copper, copper, titanium, tantalum, cobalt, silicon, titanium nitride, tantalum nitride, and tungsten. The semiconductor substrates may also contain layers of interlayer dielectrics, polysilicon, silicon oxide, silicon nitride, silicon carbide, titanium oxide, and carbon doped silicon oxides.

A semiconductor substrate can be contacted with the etching composition by any suitable method, such as placing the etching composition into a tank and immersing and/or submerging the semiconductor substrate into the etching composition, spraying the etching composition onto the semiconductor substrate, streaming the etching composition onto the semiconductor substrate, or any combinations thereof.

The etching composition of the present disclosure can be effectively used up to a temperature of about 85° C. (e.g., from about 20° C. to about 80° C., from about 55° C. to about 65° C., or from about 60° C. to about 65° C.). The etch rates of SiGe increase with temperature in this range, thus the processes at a higher temperature can be run for shorter times. Conversely, lower etching temperatures typically require longer etching times.

Etching times can vary over a wide range depending on the particular etching method, thickness, and temperature employed. When etching in an immersion batch type process, a suitable time range is, for example, up to about 10 minutes (e.g., from about 1 minute to about 7 minutes, from about 1 minute to about 5 minutes, or from about 2 minutes to about 4 minutes). Etching times for a single wafer process can range from about 30 seconds to about 5 minutes (e.g., from about 30 seconds to about 4 minutes, from about 1 minute to about 3 minutes, or from about 1 minute to about 2 minutes).

To further promote the etching ability of the etching composition of the present disclosure, mechanical agitation means can be employed. Examples of suitable agitation means include circulation of the etching composition over the substrate, streaming or spraying the etching composition over the substrate, and ultrasonic or megasonic agitation during the etching process. The orientation of the semiconductor substrate relative to the ground can be at any angle. Horizontal or vertical orientations are preferred.

Subsequent to the etching, the semiconductor substrate can be rinsed with a suitable rinse solvent for about 5 seconds up to about 5 minutes with or without agitation means. Multiple rinse steps employing different rinse solvents can be employed. Examples of suitable rinse solvents include, but are not limited to, deionized (DI) water, methanol, ethanol, isopropyl alcohol, N-methylpyrrolidinone, gamma-butyrolactone, dimethyl sulfoxide, ethyl lactate and propylene glycol monomethyl ether acetate. Alternatively, or in addition, aqueous rinses with pH>8 (such as dilute aqueous ammonium hydroxide) can be employed. Examples of rinse solvents include, but are not limited to, dilute aqueous ammonium hydroxide, DI water, methanol, ethanol, and isopropyl alcohol. The rinse solvent can be applied using means similar to that used in applying an etching composition described herein. The etching composition may have been removed from the semiconductor substrate prior to the start of the rinsing step or it may still be in contact with the semiconductor substrate at the start of the rinsing step. In some embodiments, the temperature employed in the rinsing step is between 16° C. and 27° C.

Optionally, the semiconductor substrate is dried after the rinsing step. Any suitable drying means known in the art can be employed. Examples of suitable drying means include spin drying, flowing a dry gas across the semiconductor substrate, or heating the semiconductor substrate with a heating means such as a hotplate or infrared lamp, Maragoni drying, rotagoni drying, IPA drying or any combinations thereof. Drying times will be dependent on the specific method employed but are typically on the order of 30 seconds up to several minutes.

In some embodiments, the etching method described herein further includes forming a semiconductor device (e.g., an integrated circuit device such as a semiconductor chip) from the semiconductor substrate obtained by the method described above.

The present disclosure is illustrated in more detail with reference to the following examples, which are for illustrative purposes and should not be construed as limiting the scope of the present disclosure.

### EXAMPLES

Any percentages listed are by weight (wt %) unless otherwise specified.

Controlled stirring during testing was done with a 1 inch stirring bar at 300 rpm unless otherwise noted.

### General Procedure 1

### Formulation Blending

Samples of etching compositions were prepared by adding, while stirring, to the calculated amount of the solvent the remaining components of the formulation. After a uniform solution was achieved, optional additives, if used, were added.

### General Procedure 2

### Materials and Methods

Blanket film etch rate measurements on films were carried out using commercially available unpatterned 300 mm diameter wafers that were diced into 0.5″×1.0″ test coupons for evaluation. Primary blanket film materials used for testing include 1) a SiGe film of about 500 Å thickness deposited on a silicon substrate; 2) a polysilicon film of about 1000 Å thickness deposited on a silicon substrate; and 3) a SiOx film of about 1200 Å thickness deposited on a silicon substrate.

The blanket film test coupons were measured for pre-treatment and post-treatment thickness to determine blanket film etch rates. For the SiGe, SiOx, and polysilicon blanket films, the film thicknesses were measured pre-treatment and post-treatment by Ellipsometry using a Woollam VASE.

Patterned test coupons SiGe (3 nm)/Si were evaluated for materials compatibility and/or etching responses. The post-treatment test coupons were then subjected to evaluation by scanning electron microscopy (SEM). The SEM images from the post treatment coupon were compared to a previously taken pre-treatment SEM image set to evaluate materials compatibility and etching response of each test formulation with the patterned test device features.

### General Procedure 3

### Etching Evaluation with Beaker Test

All blanket film etch testing was carried out at room temperature (25° C.) in a 200 mL PFA bottle containing 100 g of a sample solution with continuous stirring at 250 rpm. All blanket test coupons having a blanket dielectric film exposed on one side to the sample solution were diced by diamond scribe into 0.5″×1.0″ square test coupon size for beaker scale testing. Each individual test coupon was held into position using a single 4″ long, locking plastic tweezers clip. The test coupon, held on one edge by the locking tweezers clip, was suspended into the 200 mL PFA bottle and immersed into the 100 g test solution while the solution was stirred continuously at 250 rpm at room temperature (25° C.). The test coupons were held static in the stirred solution until the treatment time (as described in General Procedures 3A) had elapsed. After the treatment time in the test solution had elapsed, the sample coupons were immediately removed from the 200 mL PFA bottle and rinsed according to General Procedure 3A. After the final DIW rinse step, all test coupons were subject to a filtered nitrogen gas blow off step using a handheld nitrogen gas blower which forcefully removed all traces of DIW to produce a final dry sample for test measurements.

### General Procedure 3A (Blanket Test Coupons)

Immediately after a treatment time of 2 to 10 minutes according to General Procedure 3, the coupon was immersed in a 300 mL volume of ultra-high purity deionized (DI) water for 15 seconds with mild agitation, which was followed by 300 mL of deionized (DI) water for 15 seconds with mild agitation, and a final rinse in flow of DIW for 15 seconds. The processing was completed according to General Procedure 3.

### Example 1

Formulation Examples 1-3 (FE-1 to FE-3) were prepared according to General Procedure 1, and evaluated according to General Procedures 2 and 3A. The formulations and the test results are summarized in Table 1.

TABLE 1

| Composition [wt %] | FE-1 | FE-2 | FE-3 | CFE-1 |
|---|---|---|---|---|
| Hydrofluoric acid | 0.117% | 0.117% | 0.117% | 0.117% |
| Hydrogen Peroxide | 5.87% | 5.87% | 5.87% | 5.87% |
| Glacial Acetic Acid | 20.0% | 20.0% | 20% | 20% |
| Sulfuric acid | 0.653% | 0.653% | 0.653% | 0.653% |
| Acetic anhydride | 56.415% | 56.415% | 56.415% | 56.415% |
| Takesurf A-47Q | 0.01% | 0.01% | 0.01% | 0.01% |
| Amine | 0.01% APDA | 0.01% APDA | 0.01% APDA | 0.01% APDA |
| Silicon-containing | 0.10% Si-1 | 0.10% Si-2 | 0.10% Si-3 | 0 |
| compound | | | | |
| Water | 16.825% | 16.825% | 16.825% | 16.925% |
| Total | 100% | 100% | 100% | 100% |
| SiGe25 ER (Å/min) | 115.46 | 99.69 | 100.14 | 96.67 |
| SiO2 ER (Å/min) | 3.61 | 1.93 | 2.64 | 4.24 |
| Si on SiGe(Å/min) | 1.51 | 1.06 | 1.38 | 1.72 |
| SiGe25/SiO | 31.98 | 51.65 | 37.93 | 22.80 |
| SiGe25/Si on SiGe | 113.95 | 94.04 | 72.56 | 56.21 |

Si-1 = polybutadiene with pendant trialkoxysilane, pendant vinyl moieties
Si-2 = polybutadiene with pendant trialkoxysilane moieties
Si-3 = polybutadiene with pendant trialkoxysilane, pendant maleic anhydride moieties
APDA = N-(3-aminopropyl)-diethanolamine
SiGe25 = a SiGe film containing 25 wt % Ge
ER = etch rate

As shown in Table 1, FE-1 to FE-3 exhibited a marked increase in SiGe25/SiO selectivity compared to CFE-1. In other words, these formulations could effectively remove the SiGe film while minimizing the removal of exposed SiO on a semiconductor substrate during the etching process.

While the invention has been described in detail with reference to certain embodiments thereof, it will be understood that modifications and variations are within the spirit and scope of that which is described and claimed.

What is claimed is:

1. An etching composition, comprising:
at least one fluorine-containing acid, the at least one fluorine-containing acid comprising hydrofluoric acid or hexafluorosilicic acid;
at least one oxidizing agent;
at least one organic acid or an anhydride thereof, or a combination thereof;
at least one silicon-containing compound;
and
water.

2. The composition of claim 1, wherein the at least one fluorine-containing acid is in an amount of from about 0.01 wt % to about 2 wt % of the composition.

3. The composition of claim 1, wherein the at least one oxidizing agent comprises hydrogen peroxide or peracetic acid.

4. The composition of claim 1, wherein the at least one oxidizing agent is in an amount of from about 5 wt % to about 10 wt % of the composition.

5. The composition of claim 1, wherein the at least one organic acid comprises formic acid, acetic acid, propionic acid, or butyric acid.

6. The composition of claim 1, wherein the at least one anhydride thereof comprises formic anhydride, acetic anhydride, propionic anhydride, or butyric anhydride.

7. The composition of claim 1, wherein the composition comprises an organic acid and an anhydride thereof.

8. The composition of claim 7, wherein the organic acid is acetic acid and the anhydride is acetic anhydride.

9. The composition of claim 1, wherein the at least one organic acid is in an amount of from about 10 wt % to about 30 wt % of the composition.

10. The composition of claim 1, wherein the at least one anhydride thereof is in an amount of from about 40 wt % to about 70 wt % of the composition.

11. The composition of claim 1, wherein the water is in an amount of from about 5 wt % to about 30 wt % of the composition.

12. The composition of claim 1, wherein the silicon-containing compound comprises a siloxane or a silazane.

13. The composition of claim 12, wherein the silicon-containing compound is tetraethoxysilane, triethoxymethylsilane, hexamethyldisilazane, or tetramethyldisilazane.

14. The composition of claim 1, wherein the silicon-containing compound is a silane-modified polymer.

15. The composition of claim 14, wherein the silane-modified polymer comprises a silane-modified olefin polymer.

16. The composition of claim 15, wherein the silane-modified olefin polymer is polyethylene, polypropylene, polybutadiene, polyisoprene, polystyrene, or copolymers thereof.

17. The composition of claim 16, wherein the silane-modified olefin polymer comprises polybutadiene.

18. The composition of claim 14, wherein the silane-modified polymer comprises at least one trialkoxysilyl moiety.

19. The composition of claim 18, wherein each alkoxy moiety is independently C₁-C₅ alkoxy.

20. The composition of claim 1, further comprising at least one polymerized naphthalene sulfonic acid.

21. The composition of claim 20, wherein the at least one polymerized naphthalene sulfonic acid comprises a sulfonic acid having a structure of 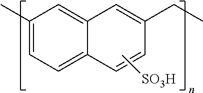
in which n is 3 to 6.

22. The composition of claim 20, wherein the at least one polymerized naphthalene sulfonic acid is in an amount of from about 0.005 wt % to about 0.15 wt % of the composition.

23. The composition of claim 1, further comprising at least one amine, the at least one amine comprising an amine of formula (I): N—R₁R₂R₃, wherein R¹ is C₁-C₈ alkyl optionally substituted by OH or NH₂, R₂ is H or C₁-C₈ alkyl optionally substituted by OH, and R₃ is C₁-C₈ alkyl optionally substituted by OH.

24. The composition of claim 23, wherein the amine of formula (I) is diisopropylamine, N-butyldiethanolamine, N-(3-aminopropyl)-diethanolamine, N-octylglucamine, N-ethylglucamine, N-methylglucamine, or 1-[bis(2-hydroxyethyl) amino]-2-propanol.

25. The composition of claim 23, wherein the at least one amine is in an amount of from about 0.001 wt % to about 0.15 wt % of the composition.

26. The composition of claim 1, further comprising an inorganic acid.

27. The composition of claim 26, wherein the inorganic acid is sulfuric acid, nitric acid, or phosphoric acid.

28. The composition of claim 1, wherein the composition has a pH less than 1.

29. A method, comprising:
contacting a semiconductor substrate containing a SiGe film with a composition of claim 1 to substantially remove the SiGe film.

30. The method of claim 29, wherein the SiGe film comprises from about 10 wt % to about 30 wt % Ge.

31. The method of claim 29, further comprising rinsing the semiconductor substrate with a rinse solvent after the contacting step.

32. The method of claim 31, further comprising drying the semiconductor substrate after the rinsing step.

33. The method of claim 29, wherein the method does not substantially remove SiN, poly-Si, or SiCO.

34. An article formed by the method of claim 29, wherein the article is a semiconductor device.

35. The article of claim 34, wherein the semiconductor device is an integrated circuit.
